(19) United States
(12) Patent Application Publication
(10) Pub. No.: US 2022/0320002 A1
(43) Pub. Date: Oct. 6, 2022

(54) STRUCTURE FOR ALIGNMENT MEASUREMENT MARK AND METHOD FOR ALIGNMENT MEASUREMENT

(71) Applicant: CHANGXIN MEMORY TECHNOLOGIES, INC., Hefei City (CN)

(72) Inventor: Wenqi LIU, Hefei (CN)

(21) Appl. No.: 17/680,377

(22) Filed: Feb. 25, 2022

Related U.S. Application Data
(63) Continuation of application No. PCT/CN2021/113467, filed on Aug. 19, 2021.

(30) Foreign Application Priority Data
Apr. 2, 2021 (CN) 202110360791.9

(51) Int. Cl. H01L 23/544; G03F 1/42; G01B 11/27

(52) U.S. Cl. CPC H01L 23/544; G03F 1/42; G01B 11/272; H01L 2223/54426

(57) ABSTRACT

The application provides a structure for an alignment measurement mark and a method for an alignment measurement, and includes a first overlay mark and a second overlay mark. The second overlay mark includes a pattern structure to be measured. A layer where the first overlay mark is located is adjacent to a layer where the second overlay mark is located. An orthographic projection of the first overlay mark onto the layer where the second overlay mark is located is located at an inner side of the second overlay mark, or an orthographic projection of the first overlay mark onto the layer where the second overlay mark is located is located at a periphery of the second overlay mark.

### CROSS-REFERENCE TO RELATED APPLICATION

This application is a U.S. continuation application of International Application No. PCT/CN2021/113467, filed on Aug. 19, 2021, which claims priority to Chinese patent application No. 202110360791.9, filed on Apr. 2, 2021. International Application No. PCT/CN2021/113467 and Chinese patent application No. 202110360791.9 are incorporated herein by reference in their entireties.

### TECHNICAL FIELD

The disclosure relates to the field of integrated circuit technologies, and in particular, to a structure for an alignment measurement mark and a method for an alignment measurement.

### BACKGROUND

In existing semiconductor processes, a process such as photolithography involves the arrangement of an alignment pattern. The alignment pattern is subjected with an optical alignment to implement the alignment between layers. However, at present, an alignment pattern can only be used for alignment and does not serve any other purpose.

In addition, in the existing semiconductor processes, the measurement on a pattern to be measured is usually a separate process step independent of alignment, and is usually performed in a vacuum cavity by using a Scanning Electron Microscope (SEM). In a measurement process, especially when the pattern to be measured is located on the surface of a thick photoresist layer, a large amount of gas byproducts would be generated, and the generated gas byproducts would contaminate a wafer in the vacuum cavity.

### SUMMARY

An aspect of embodiments of the disclosure provides a structure for an alignment measurement mark. The structure for the alignment measurement mark includes a first overlay mark and a second overlay mark. The second overlay mark includes a pattern structure to be measured.

A layer where the first overlay mark is located is adjacent to a layer where the second overlay mark is located. An orthographic projection of the first overlay mark onto the layer where the second overlay mark is located is located at an inner side of the second overlay mark, or an orthographic projection of the first overlay mark onto the layer where the second overlay mark is located is located at a periphery of the second overlay mark.

Another aspect of the embodiments of the disclosure provides a method for an alignment measurement being performed based on the foregoing structure for the alignment measurement mark. The method includes the following operations.

Signals are continuously acquired from one side to an other opposite side of the structure for the alignment measurement mark in a first direction.

Signals are continuously acquired from one side to an other opposite side of the structure for the alignment measurement mark in a second direction.

It is determined, according to a measurement structure, whether the first overlay mark is aligned with the second overlay mark are aligned. A critical size of the second overlay mark is obtained according to a measurement result.

The details of the various embodiments of the disclosure will be illustrated in the accompanying drawings and description below. Other features, problems resolved, and technical effects of the disclosure will be readily understood by those skilled in the art in light of the description in the specification, accompanying drawings, and claims.

### BRIEF DESCRIPTION OF THE DRAWINGS

Reference may be made to one or more of the accompanying drawings for the purpose of better describing and illustrating the embodiments of the disclosure. However, the details or examples additionally used to describe the accompanying drawings should not be considered as limiting the scope of any of the inventions created, embodiments currently described, or preferred implementations of the disclosure.

FIG. 1 to FIG. 8 schematically show top views of the structures of different structures of an alignment measurement mark according to the disclosure, respectively.

FIG. 9 shows a flowchart of a method for an alignment measurement according to the disclosure.

FIG. 10 shows a schematic view of the measurement of an alignment measurement mark by a method for an alignment measurement according to the disclosure.

### DETAILED DESCRIPTION

For ease of understanding of the disclosure, the disclosure is described more completely below with reference to the accompanying drawings. The preferential embodiments of the disclosure are given in the accompanying drawings. However, the disclosure may be implemented in various forms, and is not limited to the embodiments described herein. Rather, these embodiments are provided so that contents of the disclosure will be disclosed more thorough and complete.

Unless otherwise defined, the technical terms and scientific terms used herein have the same meanings as those generally understood by a person skilled in the art to which the disclosure pertains. The terms used herein in the specification of the disclosure are merely used for describing specific embodiments, but are not intended to limit the disclosure. The term “and/or” used herein encompasses any and all possible combinations of one or more of the associated listed items.

In the description of the disclosure, it needs to be understood that orientation or location relationships indicated by terms “up”, “down”, “vertical”, “horizontal”, “inside”, and “outside” are based on orientation or location relationships shown in the accompanying drawings, and are only used to facilitate description of the disclosure and simplify description, but are not used to indicate or imply that the apparatuses or elements must have specific orientations or are constructed and operated by using specific orientations, and therefore, cannot be understood as a limitation to the disclosure.

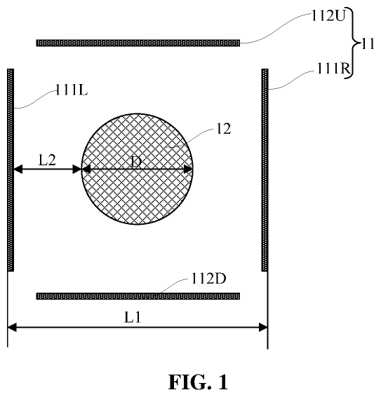

Referring to FIG. 1, the disclosure provides a structure for an alignment measurement mark. The structure includes a first overlay mark 11 and a second overlay mark 12. The second overlay mark 12 includes a pattern structure to be measured. An orthographic projection of the first overlay mark 11 onto a layer where the second overlay mark 12 is located is located at a periphery of the second overlay mark 12.

In another example, a layer where the first overlay mark 11 is located may be adjacent to a layer where the second overlay mark 12 is located, and an orthographic projection of the first overlay mark 11 onto the layer where the second overlay mark 12 is located is located on an inner side of the second overlay mark 12.

In the structure for the alignment measurement mark in the disclosure, the pattern structure to be measured is arranged as the second overlay mark 12. When the structure for the alignment measurement mark is used for alignment, the measurement of the pattern structure to be measured can be implemented. Therefore, the working efficiency of alignment measurement can be improved. In addition, the structure for the alignment measurement mark in the disclosure may measure the pattern to be measured by using an optical measurement manner, without the generation of gas byproducts during the measurement process, thereby preventing a wafer from contamination.

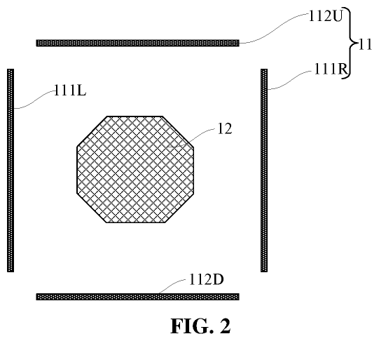

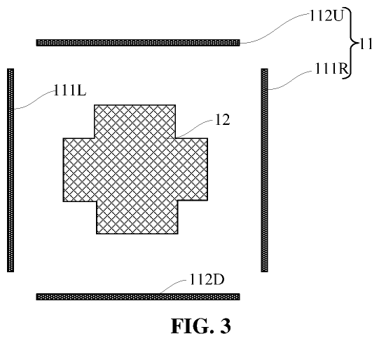

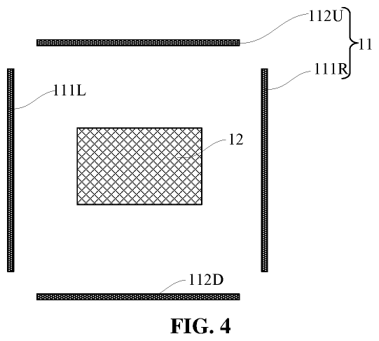

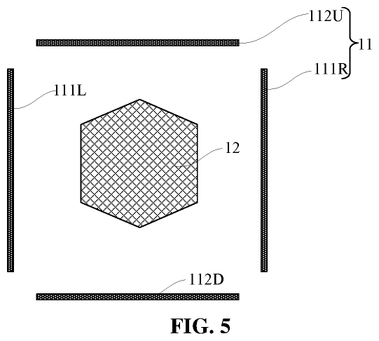

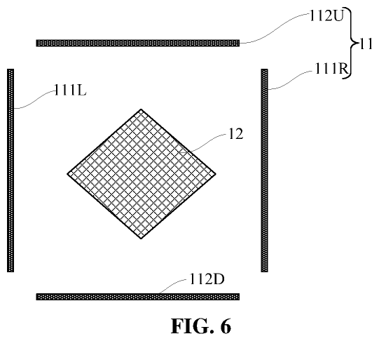

In an example, the shape of the second overlay mark 12 may be flexibly arranged according to an actual requirement. In FIG. 1, for example, the shape of the second overlay mark 12 may be a circle. However, in another example, the shape of the second overlay mark 12 may be, but not limited to, a cross (as shown in FIG. 3) or a regular polygon, for example, an octagon (as shown in FIG. 2), a rectangle (as shown in FIG. 4), a hexagon (as shown in FIG. 5), a rhombus (as shown in FIG. 6), or the like.

In an example, the second overlay mark 12 may be a pattern to be measured that does not have a high measurement accuracy requirement. For example, the second overlay mark 12 may include, but not limited to, a through-silicon via pattern. In this example, the pattern to be measured is not limited to corresponding to the second overlay mark 12 is not limited.

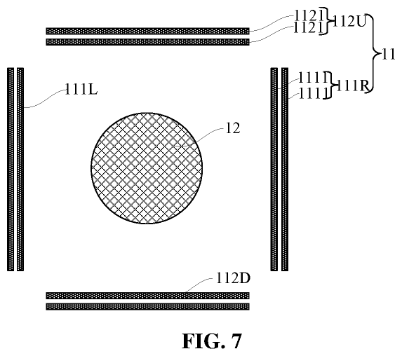

In an example, when the orthographic projection of the first overlay mark 11 onto the layer where the second overlay mark 12 is located is located on the periphery of the second overlay mark 12, as shown in FIG. 1 to FIG. 7, the first overlay mark 11 may include a first alignment pattern 111L and 111R and second alignment pattern 112U and 112D.

An orthographic projection of the first alignment pattern 111L and 111R onto the layer where the second overlay mark 12 is located is located on two opposite sides of the second overlay mark 12. The first alignment pattern 111L and 111R extends in a first direction. In FIG. 1 to FIG. 7, for example, the orthographic projection of the first alignment pattern 111L and 111R onto the layer where the second overlay mark 12 is located is located on the left side and the right side of the second overlay mark 12. That is, the orthographic projection of the first alignment pattern 111L onto the layer where the second overlay mark 12 is located is located on the left side of the second overlay mark 12, and the orthographic projection of the first alignment pattern 111R onto the layer where the second overlay mark 12 is located is located on the right side of the second overlay mark 12.

An orthographic projection of the second alignment patterns 112U and 112D onto the layer where the second overlay mark 12 is located is located on two opposite sides of the second overlay mark 12, and is located on outer sides of the first alignment pattern 111L and 111R. The second alignment pattern 112U and 112D has spacing from the first alignment pattern 111L and 111R. The second alignment pattern 112U and 112D extends in a second direction. The second direction is orthogonal to the first direction. In FIG. 1 to FIG. 7, for example, the orthographic projection of the second alignment pattern 112U and 112D onto the layer where the second overlay mark 12 is located is located on the front side and the rear side of the second overlay mark 12. That is, the orthographic projection of the second alignment pattern 112D onto the layer where the second overlay mark 12 is located is located on the front side of the second overlay mark 12, and the orthographic projection of the second alignment pattern 112U onto the layer where the second overlay mark 12 is located is located on the rear side of the second overlay mark 12.

In an example, as shown in FIG. 1 to FIG. 6, the first alignment pattern 111L or 111R includes a single first alignment structure 1111, and the second alignment pattern 112U or 112D includes a single second alignment structure 1121. That is, the orthographic projection of the first alignment pattern 111L or 111R onto the layer where the second overlay mark 12 is located has only one first alignment structure 1111 or one second alignment structure 1121 in the layer of the second overlay mark 12. In FIG. 1 to FIG. 6, the first alignment pattern 111L is one first alignment structure 1111, and the second alignment pattern 112U or 112D is one second alignment structure 1121.

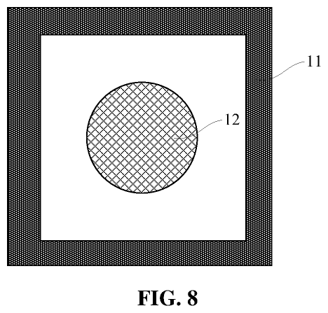

In an example, as shown in FIG. 8, the first alignment pattern 111L or 111R may include a plurality of first alignment structures 1111 arranged in parallel at intervals, and the second alignment pattern 112U or 112D may include a plurality of second alignment structures 1121 arranged in parallel at intervals. It needs to be noted that in FIG. 8, for example, the first alignment pattern 111L or 111R includes two first alignment structures 1111 arranged in parallel at an interval, and the second alignment pattern 112U or 112D includes two second alignment structures 1121 arranged in parallel at an interval. In another example, there is no limitation on the specific number of first alignment structures 1111 in the first alignment pattern 111L or 111R or the specific number of second alignment structures 1121 in the second alignment pattern 112U or 112D.

In an example, specific structures of the first alignment structure 1111 and the second alignment structure 1121 may be identical or may be different. In this example, the first alignment structure 1111 and the second alignment structure 1121 may both be, but not limited in the structure of strip.

In an example, the length of the first alignment structure 1111 and the length of the second alignment structure 1121 may be set according to an actual requirement. In this example, the length of the first alignment structure 1111 is greater than a size of the second overlay mark 12 in the first direction, and the length of the first alignment structure 1111 is greater than a size of the second overlay mark 12 in the second direction.

In an example, continuing to refer to FIG. 1, a size D of the second overlay mark 12 in the first direction or the second direction is not less than 3 μm. Specifically, the size D of the second overlay mark 12 in the first direction or the second direction may be 3 μm, 4 μm, 5 μm, 8 μm, 10 μm, or the like. A size L1 of the first overlay mark 11 in the first direction or the second direction is 30 μm to 80 μm. Specifically, the size L1 of the first overlay mark 11 in the first direction or the second direction may be 30 μm, 40 μm, 50 μm, 60 μm, 70 μm, 80 μm, or the like. A spacing L2 between an edge of the orthographic projection of the first overlay mark 11 onto the layer where the second overlay mark 12 is located and the second overlay mark 12 is not less than 2 μm. Specifically, the spacing L2 between the edge of the orthographic projection of the first overlay mark 11 onto the layer where the second overlay mark 12 is located and the second overlay mark 12 may be 2 μm, 3 μm, 4 μm, 5 μm, 10 μm, or the like.

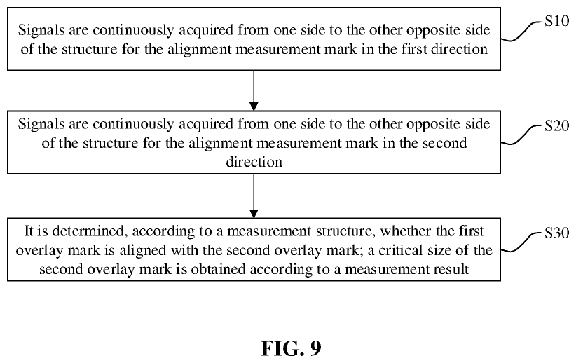

In still another embodiment, as shown in FIG. 9, the first overlay mark 11 may include an annular overlay mark.

In an example, the center of the first overlay mark 11 may be overlapped with the center of the second overlay mark 12.

In an example, the first overlay mark 11 and/or the second overlay mark 12 may be located on the surface of a photoresist layer. That is, at least one of the first overlay mark 11 and the second overlay mark 12 is located on the surface of the photoresist layer.

In another embodiment, referring to FIG. 9 in combination with FIG. 1 to FIG. 8, the disclosure further provides a method for an alignment measurement. In the method for the alignment measurement in the disclosure, alignment measurement is performed based on the structure for the alignment measurement mark in the foregoing embodiments. The specific structure of the structure for the alignment measurement mark may be referred to FIG. 1 to FIG. 8 and related text description. Details are not described herein again. The alignment measurement method includes the following operations.

At S10, signals are continuously acquired from one side to the other opposite side of the structure for the alignment measurement mark in the first direction.

At S20, signals are continuously acquired from one side to the other opposite side of the structure for the alignment measurement mark in the second direction.

At S30, it is determined, according to a measurement structure, whether the first overlay mark 11 is aligned with the second overlay mark 12. And a critical size of the second overlay mark is obtained according to a measurement result.

In the method for the alignment measurement in the disclosure, measurement is performed by the specific measurement manner that signals are continuously acquired from one side to the other side of the structure for the alignment measurement mark in both the first direction and the second direction, so that alignment and measurement can be simultaneously implemented, thereby improving the working efficiency of alignment and measurement. Meanwhile, in the structure for the alignment measurement mark in the disclosure, the pattern to be measured may be measured by an optical measurement manner, without the generation of gas byproducts during the measurement process, thereby preventing a wafer from contamination.

In an example, the structure for the alignment measurement mark is measured by using an optical measurement tool based on a measurement light path.

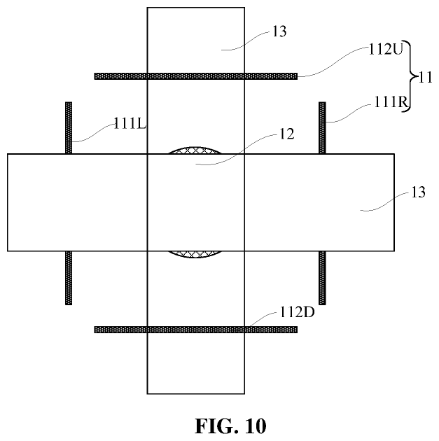

In an example, as shown in FIG. 10, the center of the first overlay mark 11 is overlapped with the center of the second overlay mark 12. Both a measurement light path 13 of continuously acquiring signals from one side to the other opposite side of the structure for the alignment measurement mark in the first direction and a measurement light path 13 of continuously acquiring signals from one side to the other opposite side of the structure for the alignment measurement mark in the second direction pass through the center of the first overlay mark 11 and the center of the second overlay mark 12. That is, by the measurement light path 13, signals may be continuously acquired from a side of the first alignment pattern 111L away from the second overlay mark 12 to a side of the first alignment pattern 111R away from the second overlay mark 12, and signals may be continuously acquired from a side of the second alignment pattern 112U away from the second overlay mark 12 to a side of the second alignment pattern 112D away from the second overlay mark 12. The acquisitions by both the measurement light paths 13 pass through the second overlay mark 12. In existing alignment methods, a plurality of block-shaped measurement regions are separately selected from the first overlay mark 11 and the second overlay mark 12 to acquire signals in a stepwise manner. Boundaries of the measurement regions are determined according to a sudden change in measurement signals. According to a determination result, it is then determined whether the first overlay mark 11 is aligned with the second overlay mark 12. However, the existing alignment methods are susceptible to the interference of impurity noise. The interference of impurity noise causes incorrect determination, resulting in an inaccurate determination result. In the method of the disclosure, a relatively complete signal interval is acquired by means of a manner of continuously acquiring signals. Therefore, impurity noise can be recognized, preventing the impurity noise from interfering with acquired signals, and improving the accuracy of alignment measurement.

In an example, when the orthographic projection of the first overlay mark 11 onto the layer where the second overlay mark 12 is located is located on the periphery of the second overlay mark 12, the width of a measurement light path 13 of continuously acquiring signals from one side to the other opposite side of the structure for the alignment measurement mark in the first direction and the width of a measurement light path 13 of continuously acquiring signals from one side to the other opposite side of the structure for the alignment measurement mark in the second direction may both be 0.5 times to 1 time the width of the second overlay mark 12. Specifically, the width of the measurement light path 13 of continuously acquiring signals from one side to the other opposite side of the structure for the alignment measurement mark in the first direction and the width of the measurement light path 13 of continuously acquiring signals from one side to the other opposite side of the structure for the alignment measurement mark in the second direction may both be 0.5 times, 0.6 times, 0.7 times, 0.8 times, 0.9 times or 1 time of the width of the second overlay mark 12.

The technical features in the foregoing embodiments may be randomly combined. For simplicity of description, it is not described all possible combinations of the technical features in the foregoing embodiments. However, it should be considered that these combinations of technical features fall within the scope recorded in the specification provided that these combinations of technical features do not have any conflict.

The foregoing embodiments only describe several embodiments of the disclosure, and their description is specific and detailed, but cannot therefore be understood as a limitation to the claims of the disclosure. It should be noted that for a person of ordinary skill in the art, several variations and improvements may further be made without departing from the concept of the disclosure. These variations and improvements should also be deemed as falling within the protection scope of the disclosure. Therefore, the scope of protection of the patent of the disclosure shall be subject to the appended claims.

1. A structure for an alignment measurement mark, comprising:
a first overlay mark; and
a second overlay mark, comprising a pattern structure to be measured;
wherein a layer where the first overlay mark is located is adjacent to a layer where the second overlay mark is located, and an orthographic projection of the first overlay mark onto the layer where the second overlay mark is located, is located at an inner side of the second overlay mark, or an orthographic projection of the first overlay mark onto the layer where the second overlay mark is located, is located at a periphery of the second overlay mark.

2. The structure for the alignment measurement mark according to claim 1, wherein the second overlay mark comprises a shape of a circle, a cross or a regular polygon.

3. The structure for the alignment measurement mark according to claim 1, wherein the second overlay mark comprises a through-silicon via pattern.

4. The structure for the alignment measurement mark according to claim 1, wherein when the orthographic projection of the first overlay mark onto the layer where the second overlay mark is located, is located on the periphery of the second overlay mark, the first overlay mark comprises:
a first alignment pattern, wherein an orthographic projection of the first alignment pattern onto the layer where the second overlay mark is located, is located on two opposite sides of the second overlay mark, the first alignment pattern extends in a first direction; and
a second alignment pattern, wherein an orthographic projection of the second alignment pattern onto the layer where the second overlay mark is located, is located on two opposite sides of the second overlay mark, and on outer sides of the first alignment pattern, the second alignment pattern has a spacing from the first alignment pattern, the second alignment pattern extends in a second direction, the second direction is orthogonal to the first direction.

5. The structure for the alignment measurement mark according to claim 4, wherein the first alignment pattern comprises a single first alignment structure and the second alignment pattern comprises a single second alignment structure.

6. The structure for the alignment measurement mark according to claim 4, wherein the first alignment pattern comprises a plurality of first alignment structures arranged in parallel at intervals, and the second alignment pattern comprises a plurality of second alignment structures arranged in parallel at intervals.

7. The structure for the alignment measurement mark according to claim 5, wherein the single first alignment structure and the single second alignment structure are both in a structure of strip.

8. The structure for the alignment measurement mark according to claim 6, wherein the first alignment structures and the second alignment structures are both in a structure of strip.

9. The structure for the alignment measurement mark according to claim 5, wherein the single first alignment structure has a length greater than a size of the second overlay mark in the first direction and greater than a size of the second overlay mark in the second direction.

10. The structure for the alignment measurement mark according to claim 6, wherein the first alignment structures have a length greater than a size of the second overlay mark in the first direction and greater than a size of the second overlay mark in the second direction.

11. The structure for the alignment measurement mark according to claim 4, wherein a size of the second overlay mark in the first direction or the second direction is not less than 3 μm, a size of the first overlay mark in the first direction or the second direction is 30 μm to 80 μm, and the spacing between the second overlay mark and an edge of the orthographic projection of the first overlay mark onto the layer where the second overlay mark is located, is not less than 2 μm.

12. The structure for the alignment measurement mark according to claim 1, wherein the first overlay mark comprises an annular overlay mark.

13. The structure for the alignment measurement mark according to claim 1, wherein a center of the first overlay mark is overlapped with a center of the second overlay mark.

14. The structure for the alignment measurement mark according to claim 1, wherein at least one of the first overlay mark or the second overlay mark is located on a surface of a photoresist layer.

15. A method for an alignment measurement being performed based on the structure for the alignment measurement mark according to claim 1, comprising:
continuously acquiring signals from one side to an other opposite side of the structure for the alignment measurement mark in a first direction;
continuously acquiring signals from one side to an other opposite side of the structure for the alignment measurement mark in a second direction; and
determining, according to a measurement structure, whether the first overlay mark is aligned with the second overlay mark, and obtaining a critical size of the second overlay mark according to a measurement result.

16. The method for the alignment measurement according to claim 15, wherein the structure for the alignment measurement mark is measured by using an optical measurement tool based on a measurement light path.

17. The method for the alignment measurement according to claim 16, wherein a center of the first overlay mark is overlapped with a center of the second overlay mark, and a measurement light path of continuously acquiring signals from one side to the other opposite side of the structure for the alignment measurement mark in the first direction and a measurement light path of continuously acquiring signals from one side to the other opposite side of the structure for the alignment measurement mark in the second direction both pass through the center of the first overlay mark and the center of the second overlay mark.

18. The method for the alignment measurement according to claim 16, wherein when the orthographic projection of the first overlay mark onto the layer where the second overlay mark is located is located on the periphery of the second overlay mark, a width of a measurement light path of continuously acquiring signals from one side to the other opposite side of the structure for the alignment measurement mark in the first direction and a width of a measurement light path of continuously acquiring signals from one side to the other opposite side of the structure for the alignment measurement mark in the second direction are both 0.5 times to 1 time a width of the second overlay mark.
